(19) United States
(12) Patent Application Publication
(10) Pub. No.: US 2025/0216483 A1
(43) Pub. Date: Jul. 3, 2025

(54) HYPERPOLARIZATION PROCESS AND SYSTEM

(71) Applicant: Primemax Biotech Limited, Hong Kong (CN)

(72) Inventors: Juan CHENG, Hong Kong (CN); Yau Chuen YIU, Hong Kong (CN); Chak Yeung AU, Hong Kong (CN); Koon Chung HUI, Hong Kong (CN)

(73) Assignee: Primemax Biotech Limited, Hong Kong (CN)

(21) Appl. No.: 18/860,675

(22) PCT Filed: Apr. 27, 2023
(86) PCT No.: PCT/CN2023/091213

§ 371 Date: Oct. 27, 2024

(30) Foreign Application Priority Data
Apr. 27, 2022 (HK) 32022052593.7

(51) Int. Cl. G01R 33/28; G01R 33/56

(52) U.S. Cl. CPC G01R 33/282; G01R 33/5601; G01R 33/5605

(57) ABSTRACT

A process for the polarization transfer between electron spin of Nitrogen Vacancy (NV) centre to nuclear spin of Carbon-13 labelled metabolites (13C-metabolites) in ambient conditions, said process including the steps of (i) providing a mixture including host vehicles which provide a source of NV centres, and 13C-metabolites; (ii) transforming said mixture into a solid glassy state, wherein the spatial orientation of the host and electron spin state of NV centres are randomly distributed within said mixture in a solid state; and (iii) applying a hyperpolarization process to the mixture in a solid state, wherein at the end of polarization transfer process, both electron spin of NV centres and nuclear spin of carbon-13 are strongly polarized in one direction at ambient temperature.

### TECHNICAL FIELD

The present invention relates to a process and system for polarization transfer between electron spin of Nitrogen Vacancy (NV) centre to nuclear spin of Carbon-13 labelled metabolites (¹³C-metabolites), and magnetic resonance imaging (MRI) contrast agents for subsequent magnetic resonance imaging (MRI) applications.

### BACKGROUND OF THE INVENTION

Magnetic resonance imaging (MRI) has been widely used in the medical discipline for obtaining the three-dimensional structural information from a human body, for varying investigative and diagnostic purposes of a subject.

By obtaining a three-dimensional image, medical practitioners are able to see through and within the organs of a patient, and determine if there are any structural and physiological abnormalities within the body and organs of the patient.

One such abnormality is the presence of tumour tissue. Traditional MRI techniques detect 1H nuclei inside human bodies, such that the water and fat distribution can be seen. Since no ionizing radiation is involved, it can be considered to be a safer investigation method than X-ray imaging techniques.

However, detecting 1H nuclei alone cannot always distinguish normal tissue and abnormal or cancerous tissue and as such, the techniques can be considered to be less applicable than X-ray computed tomography (CT) and positron emission tomography (PET).

Therefore, in order to enhance the contrast between normal and cancerous tissue, typically contrast agents are needed to be introduced into the body of the subject.

These MRI contrast agents typically contain gadolinium, which, however, has certain toxicity effects, for example towards the kidneys and the nervous system of a patient.

Patients having renal diseases are considered susceptible to kidney failure after injection of gadolinium-based contrast agents into the body. Moreover, gadolinium can remain in human body for a prolonged period time after MRI scanning, which also inherently increases the risk of patient safety related issues.

Apart from gadolinium-based contrast agents, there has been some research on ¹³C nuclei based MRI imaging to distinguish between normal and cancerous tissues. Carbon, as is known, is the building block of all organic compounds.

Since ¹³C nuclei are stable, there is considered no harm in using ¹³C for MRI imaging in living organisms such as humans.

However, the natural abundance of ¹³C nuclei in carbon is only 1.1%, which is much smaller than the natural abundance of 99.98% of 1H nuclei in hydrogen. Moreover, ¹³C signal in MRI is much weaker than 1H.

These two factors together can be considered to make MRI by ¹³C very difficult to be used practically. Nevertheless, there has been technologies for enriching ¹³C abundance in bio-molecules. Therefore, ¹³C enhanced compounds with high purities can be obtained commercially for use in MRI imaging.

Regarding the low signal of ¹³C in comparison to 1H, there are also techniques for enhancement in the art. At room temperature, the nuclear spin alignment of ¹³C within a magnetic field is little under thermal equilibrium.

### Object of the Invention

It is an object of the present invention to provide a process and system for polarization transfer between electron spin of Nitrogen Vacancy (NV) centre to nuclear spin of Carbon-13 labelled metabolites (13C-metabolites) and magnetic resonance imaging (MRI) contrast agents for subsequent magnetic resonance imaging (MRI) applications, which overcomes or at least partly ameliorates at some deficiencies as associated with the prior art.

### SUMMARY OF THE INVENTION

In a first aspect, the present invention provides a process for the polarization transfer between electron spin of Nitrogen Vacancy (NV) centre to nuclear spin of Carbon-13 labelled metabolites (13C-metabolites) in ambient conditions, said process including the steps of:
(i) providing a mixture including host vehicles which provide a source of NV centres, and 13C-metabolites;
(ii) transforming said mixture into a solid glassy state, wherein the spatial orientation of the host and electron spin state of NV centres are randomly distributed within said mixture in a solid state; and
(iii) applying a hyperpolarization process to the mixture in a solid state, wherein at the end of polarization transfer process, both electron spin of NV centres and nuclear spin of carbon-13 are strongly polarized in one direction at ambient temperature.

The NV centre may be a source of electron spin to be polarized under hyperpolarization process in ambient conditions.

The pathway of spin transfer between electron spin of NV centre and 13C-metabolites may be singular.

Alternatively, the pathway of spin transfer between electron spin of NV centre and 13C-metabolites is plural as a result of spacing between molecules.

The spacing between molecules may include spacing between hosts of NV centre, between 13C-metabolites, host of NV centre to 13C-metabolite, nuclear spin of 13C nuclear within host to 13C-metabolites; between charges including NV centres within same host, NV centres between different hosts; or between individual surrounding charges and corresponding spin state, magnetic impurities and the like

The spacing between molecules may be provided by a spacer wherein the spacer is water molecules, solvents, saline salt, or physical size of NV centre's host.

The host of NV centre is preferably a wide band gap material with high optical transparent for Deep UV to Green light.

The host of NV centre is preferably a wide band gap material with high optical transparent for Deep UV to Green light in the range of from 200 nm to 600 nm.

The host of NV centre is preferably a micro-sized or nano-sized powder.

The host of NV centre is preferably selected from the group including boron nitride, diamond or sapphire or the like.

The host of NV centre preferably has a size between 10 nm to 100 um.

The 13C-metabolite may be selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

The majority of final polarization of nuclear spin in 13C-metabolite is preferably in same direction with few degrees discrepancy tolerance in any space coordinates.

The glassy state may be provided by the quasi-lattice bonding between 13C-metabolites, hosts and other molecules above.

The hyperpolarization process preferably includes radiating microwave energy and coherent light to 13C-metabolites and hosts of NV centres mixture under application of magnetic field.

The hyperpolarization process may include multi-cycle of excitation and manipulation of electron spin of NV centre and relaxation for spin transfer to nuclear spin of 13C-metabolites under ambient condition.

The hyperpolarization of 13C-metabolite is provided at ambient conditions.

The solid glassy state may be formed by lowering the temperature of the mixture.

The temperature may be lowered to below −20° C.

The temperature may be lowered to −35° C. or −80° C.

In a second aspect, the present invention provides a process for preparing a contrasting agent for MRI imaging of the body of a human or an animal for hyperpolarisation at ambient conditions, said process including the steps of:
(i) providing a mixture including host vehicles with NV centres and 13C-metabolites, and
(ii) transforming said mixture into a solid glassy state, wherein the spatial orientation of the host and electron spin state of NV centres are randomly distributed within said mixture in a solid state.

The spacing between molecules may include spacing between hosts of NV centre, between 13C-metabolites, host of NV centre to 13C-metabolite, nuclear spin of 13C nuclear within host to 13C-metabolites; between charges including NV centres within same host, NV centres between different hosts; or between individual surrounding charges and corresponding spin state, magnetic impurities and the like

The spacing between molecules may be provided by a spacer wherein the spacer is water molecules, solvents, saline salt, or physical size of NV centre's host.

The host of NV centre is preferably a wide band gap material with high optical transparent for Deep UV to Green light.

The host of NV centre is preferably a wide band gap material with high optical transparent for Deep UV to Green lighting the range of from 200 nm to 600 nm.

The solid glassy state may be formed by lowering the temperature of the mixture.

The temperature may be lowered to below −20° C.

The temperature may be lowered to −35° C. or −80° C.

The host of NV centre is preferably a micro-sized or nano-sized powder.

The host of NV centre preferably is selected from the group including boron nitride, diamond or sapphire or the like.

The host of NV centre preferably has a size between 10 nm to 100 um.

The 13C-metabolite may be selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

In a third aspect, a contrasting agent for MRI imaging of the body of a human or an animal for hyperpolarisation at ambient conditions, said contrasting agent comprising:
a mixture including host vehicles with NV centres and 13C-metabolites, wherein said mixture is provided in a solid glassy state, wherein the spatial orientation of the host and electron spin state of NV centres are randomly distributed within said mixture in a solid state.

The spacing between molecules may include spacing between hosts of NV centre, between 13C-metabolites, host of NV centre to 13C-metabolite, nuclear spin of 13C nuclear within host to 13C-metabolites; between charges including NV centres within same host, NV centres between different hosts; or between individual surrounding charges and corresponding spin state, magnetic impurities and the like

The spacing between molecules may be provided by a spacer wherein the spacer is water molecules, solvents, saline salt, or physical size of NV centre's host.

The host of NV centre is preferably a wide band gap material with high optical transparent for Deep UV to Green light.

The host of NV centre is preferably a wide band gap material with high optical transparent for Deep UV to Green lighting the range of from 200 nm to 600 nm.

The host of NV centre is preferably a micro-sized or nano-sized powder.

The host of NV centre is preferably selected from the group including boron nitride, diamond or sapphire or the like.

The host of NV centre preferably has a size between 10 nm to 100 um.

The 13C-metabolite may be selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

In a forth aspect, the contrasting agent for MRI imaging of the body of a human or an animal for hyperpolarisation at ambient conditions, said contrasting agent comprising: a mixture including host vehicles with NV centres and 13C-metabolites; wherein said mixture is provided for subsequent transformation into a solid glassy state, such that the spatial orientation of the host and electron spin state of NV centres are randomly distributed within said mixture in a solid state.

The host vehicles of NV centre may be a micro-sized or nano-sized powder.

The host vehicle of NV centre may be selected from the group including boron nitride, diamond or sapphire or the like.

The host of NV centre has a size between 10 nm to 100 um.

The 13C-metabolite may be selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

In a fifth aspect, the hyperpolarisation system comprising;
(i) A containment vessel for receiving a contrasting agent according to the third aspect;
(ii) A laser for providing excitation;
(iii) A microwave system; and
(iv) A magnetic resonator.

### BRIEF DESCRIPTION OF THE DRAWINGS

In order that a more precise understanding of the above-recited invention can be obtained, a more particular description of the invention briefly described above will be rendered by reference to specific embodiments thereof that are illustrated in the appended drawings.

The drawings presented herein may not be drawn to scale and any reference to dimensions in the drawings or the following description is specific to the embodiments disclosed.

FIG. 1a-FIG. 1c shows the hyperpolarization process for enhancing MRI signal of Carbon 13 nuclei;

FIG. 2a-FIG. 2b shows an example of Glassy state between electron centre provided by NV and 13C-pyruvate metabolite molecules in accordance with the present invention;

FIG. 3a is an illustration of potential spin transfer pathways between NV centre to nearby 13C nuclear and then 13C near within host to 13C-metabolites;

FIG. 3b is an illustration of NV centre electron spin to 13C-metabloites around the surface of host due to glassy state achieved in whole mixture;

FIG. 4a is an image depicting MRI imaging of hyperpolarized 13C-pyruvate mixture in accordance with the present invention, and non-processed 13C-pyruvate by Echo-Planar Spectroscopic Imaging (EPSI) pulse-sequence measurement, and shows Chemical Shift spectrum for Hyperpolarized 13C-pyruvate mixture hyperpolarised in accordance with the present invention;

FIG. 4b is a line drawing of FIG. 4a;

FIG. 5a is an image FIG. 4a, showing the time pointing the of cursor to non-processed 13C-pyruvate (right sample in the left box), and showing the Chemical Shift spectrum shows very weak signal comparing to the Hyperpolarized 13C-pyruvate mixture;

FIG. 5b is a line drawing of FIG. 5a; and

FIG. 6 shows a schematic representation of an embodiment of a hyperpolarisation system as used in the present invention.

### DETAILED DESCRIPTION OF THE DRAWINGS

The present inventors have identified shortcomings of the problems with the prior art, and have provided a process and a system which overcomes the problems of the prior art.

### Present Invention

The present inventors have developed a process and system polarization transfer between electron spin of Nitrogen Vacancy (NV) centre to nuclear spin of Carbon-13 labelled metabolites (13C-metabolites) in ambient conditions, which may be used for image contrasting purposes for MRI (Magnetic Resonance Imaging).

### Invention Background Theory

It is known within the field of diagnostic imaging, that cancer cells exhibit a unique metabolic fingerprint that provides a means to differentiate such cancer cells from benign tissue of a subject.

In order to investigate such cancer cells, Magnetic resonance imaging (MRI) is one of the tools utilised in imaging diagnostics.

In particular, ¹³C Magnetic resonance imaging (MRI) is attractive for metabolic imaging, because carbon serves as backbone of nearly all organic molecules, thus allowing the investigation in the area of cancer metabolism.

However, in practice, the signal from a ¹³C labelled tracer has been considered too weak for in vivo imaging within a subject, due to the very low natural abundance of the ¹³C isotope.

In order to improve the MRI signal of ¹³C nuclei for imaging purposes, detection probes can be synthetically enriched to increase the concentration of the ¹³C label in a molecule. MRI signal can be further enhanced dramatically by the process of hyperpolarization.

In order to enhance the ¹³C signal, the ratio of aligned nuclear spin under magnetic field is needed to be greatly increased beyond thermal equilibrium. This phenomenon is known and termed “hyperpolarization” within the art.

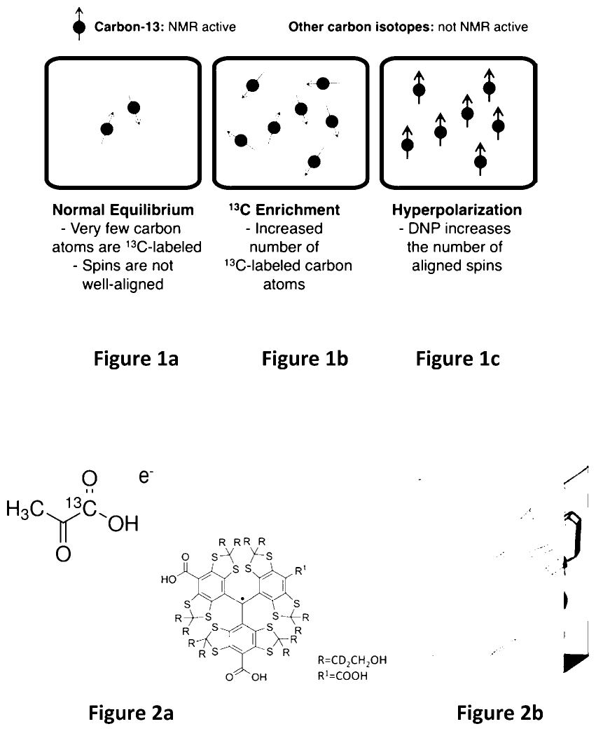

Reference to such phenomena is described below with reference to FIGS. 1a-1c.

Dynamic nuclear polarization (DNP) is a method which can hyperpolarize ¹³C so that ¹³C signal can be enhanced by 10,000-fold compared to thermal equilibrium in room temperature.

This makes use of compounds with radicals to provide lone pair electrons, whose aligned spins can polarize the nuclear spins of ¹³C. By adding radicals into ¹³C compounds at around 1 K in a magnetic field of 4.6 T to 5 T for 30 min to 90 min, the ¹³C nuclear spin can be hyperpolarized, wherein K=Kelvin and T=Tesla.

As the radicals used in DNP have certain toxicity to human cells and the DNP process has to be done in cryo-environment, there have been proposed other methods developing for the hyperpolarization of ¹³C.

The principle of hyperpolarization is the high spin polarization of a paramagnetic radical can be transferred to the ¹³C nucleus on another molecule under resonant microwave irradiation.

However, as noted by the present Inventors, conventional methods generally involve the conditions of low temperature (˜<=K) and high magnetic field (>=3 T) to first generate the electron polarization.

It is reported the hyperpolarization signal of ¹³C nuclei can be increased with a factor of 720 against the thermal signal at 7 T and retained for multiple-minute long period via optical hyperpolarization.

As is known, diamonds contain Nitrogen Vacancy (NV) centres with one negative charge captured from the surroundings.

The diamond NV-centres are paramagnetic with spin S=1 with a large zero field splitting, with D=2.87 GHz, wherein D is the energy difference between electron spin state of zero-field splitting of NV centre, the energy range is in microwave band.

Laser light can be used for optical pumping, providing excitation, to the electron spins of NV centres.

The electron spins of the NC centres can then be transferred to ¹³C atoms when the Rabi frequency of the NV centres match the Larmor frequency of ¹³C.

### Present Invention Details

In accordance with the present invention, a process system has been proposed and provided for hyperpolarizing ¹³C isotope-based Magnetic resonance imaging (MRI) contrast agents for subsequent magnetic resonance imaging (MRI) applications.

The present invention is a technology, process and system to facilitate the polarization transfer between electron spin of Nitrogen Vacancy (NV) centre to nuclear spin of Carbon-13 labelled metabolites (¹³C-metabolites) in ambient condition, for MRI image contrasting applications for human subjects or animal subjects.

Such transfer at ambient conditions, which is typical laboratory or clinical environmental conditions, such as room temperature.

In accordance with the present invention, initially NV centres and its host vehicle are provided in a glassy state with ¹³C-metabolites, whereas the spatial orientation of the host vehicle and electron spin state of NV centres are randomly distributed.

Glassy state is the iced form of the randomly mixed solution made of NV contained nanodiamond with ¹³C metabolite. Glass is a non-equilibrium, non-crystalline condensed state of matter that exhibits a glass transition. The structure of glasses is similar to that of their parent supercooled liquids (SCL), and they spontaneously relax toward the SCL state. Their ultimate fate, in the limit of infinite time, is to crystallize.

The mixture of ¹³C-metabolite is in glassy state, whereas the spatial orientation and spin states are randomly distributing around NV centre and its host material.

They host material for providing such NV centres, as may be applicable to the present invention, is nanodiamonds

At the end of polarization transfer process, both electron spin of NV centres and nuclear spin of ¹³C are strongly polarized in one direction at ambient temperature, and are ready for injection into animal or human being subjects, for in-vivo metabolic imaging by Magnetic Resonance Imaging system.

In accordance with the invention, the NV centre in is a source of electron spin to be polarized under hyperpolarization process in an ambient condition.

The pathway of spin transfer between electron spin of NV centre and ¹³C-metabolites is not necessarily singular, but may be plural due to spacing between molecules (that is between hosts of NV centre, between ¹³C-metabolites, host of NV centre to ¹³C-metabolite, nuclear spin of ¹³C nuclear within host to ¹³C-metabolite) and charges (NV centres within same host, NV centres between different hosts), individual surrounding charges and corresponding spin state, magnetic impurities and the like.

Such spacing is provided by a spacer and which may be provided one of or a mixture of water molecules, solvents, saline salt, and physical size of NV centre's host, for example.

The host of NV centre may be a wide band gap material with high optical transparency for Deep UV to Green light (for example around 200 nm to 600 nm), for example micro-sized or nano-sized powder of boron nitride, diamond or sapphire or the like.

The host of NV centre may have a variable size between 10 nm to 100 um.

The ¹³C-metabolite may be selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like

The majority of final polarization of nuclear spin in ¹³C-metabolite is typically in same direction, with few degrees discrepancy tolerance in any space coordinates.

The glassy state is provided by the quasi-lattice bonding between ¹³C-metabolites, hosts and other molecules including those as recited above.

The physical condition of hyperpolarization process of the present includes radiating microwave energy and coherent light to ¹³C-metabolites and hosts of NV centres mixture, under an applied magnetic field.

Further, the principle of hyperpolarization process of the present invention includes multi-cycle of excitation and manipulation of electron spin of NV centre, and relaxation for spin transfer to nuclear spin of ¹³C-metabolites.

In accordance with the present invention, advantageously, the hyperpolarization of ¹³C-metabolite which can be achieved in ambient condition and subjects can benefit from freshly prepared and strong signal MRI metabolic probes.

Referring to FIG. 1a-FIG. 1b, there is shown for illustrative purposes, the hyperpolarization process for enhancing MRI signal of Carbon 13 nuclei.

As is shown in FIG. 1a, Normal Equilibrium is shown, wherein very few carbon atoms are ¹³C-labeled, and spins are not well-aligned. As is shown in FIG. 1b, ¹³C Enrichment is shown, whereby there is increased ¹³C-labeled carbon atoms.

Referring to FIG. 1c, Hyperpolarization, the DNP (Dynamic Nuclear Polarization) increases the number of aligned spins.

As is shown, FIG. 2a depict the structural formulae of an example of Glassy state between electron centre provided by NV and 13C-pyruvate metabolite molecules in accordance with the present invention, wherein a glassy state refers to a non-equilibrium, non-crystalline state of matter that appears solid on a short time scale but continuously relaxes towards the liquid state. Visually, the glassy state mixture of NV and 13-C metabolites appears as an amorphous solid form as illustrated by FIG. 2b.

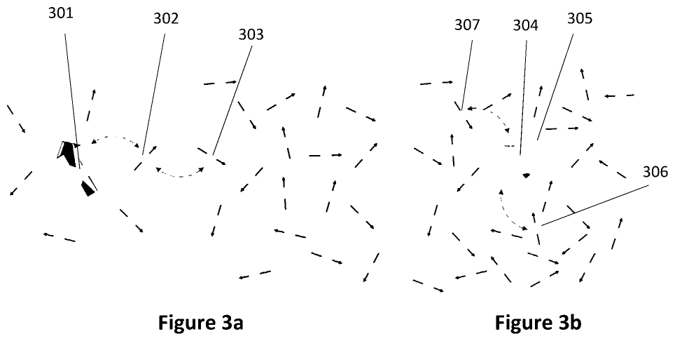

Referring to FIG. 3a, there is shown an illustration of potential spin transfer pathways between NV centre to nearby ¹³C nuclear. In this illustration, a single NV center 301 is served as the source of polarisation transfer. In order for the polarisation transfer between the NV centre 301 to nearby ¹³C nuclear to take place, the electron spin would need to be transferred in multiple steps: (i) from the NV center 301 to a first ¹³C nuclear 302 next to it, and (ii) further to a second ¹³C nuclear 303 which is in proximity to the first ¹³C nuclear 301. Such polarisation transfer process would then be slow and inefficient.

Now as shown in FIG. 3b, there is an illustration of NV (Nitrogen Vacancy) centre 304 electron spin to 13C-metabloites around the surface of host vehicle 305. A host vehicle 305 containing NV center 304 is used, instead of an individual radical, as the source of polarisation transfer, polarisation transfer can occur simultaneously from the NV center 304 to ¹³C nuclei 306 and 307 which are located around the surface of the host vehicle 305 due to the glassy state achieved in whole mixture.

Advantageously, and in accordance with the present invention and implementation thereof, the polarisation transfer process would therefore be more efficient.

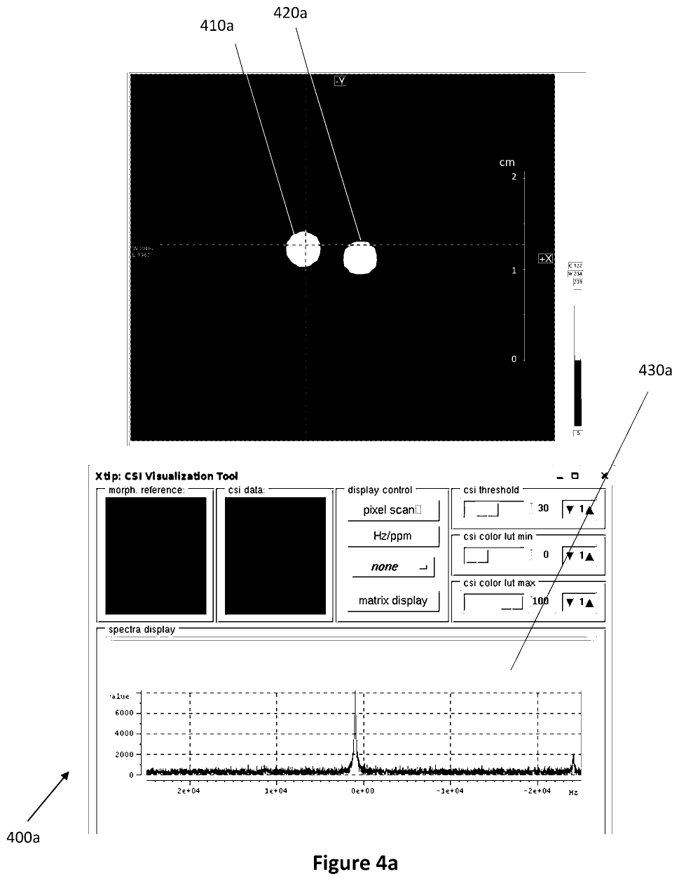

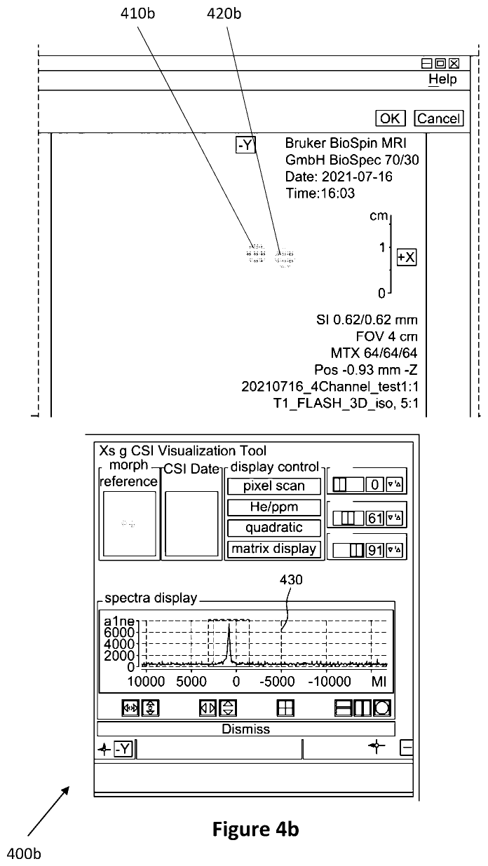

As is shown, FIG. 4a is an image 400a depicting MRI imaging of 410a Hyperpolarized 13C-pyruvate mixture (left sample in upper diagram) in accordance with the present invention, and 420a non-processed ¹³C-pyruvate (right sample in the upper diagram) by EPSI (Echo-Planar Spectroscopic Imaging) pulse-sequence measurement.

As is shown at the lower diagram of FIG. 4a, the Chemical Shift spectrum 403a shows very strong signal peak at 0.1e+04 from the Hyperpolarized 13C-pyruvate mixture.

FIG. 4b is a line drawing illustration of FIG. 4a, with 400b depicting MRI imaging of 410b Hyperpolarized 13C-pyruvate mixture (left sample in upper diagram) in accordance with the present invention, and 420b non-processed 13C-pyruvate (right sample in the upper diagram) by EPSI.

As is shown at the lower diagram of FIG. 4b, the Chemical Shift spectrum 403b shows very strong signal peak at 0.1e+04 from the Hyperpolarized 13C-pyruvate mixture.

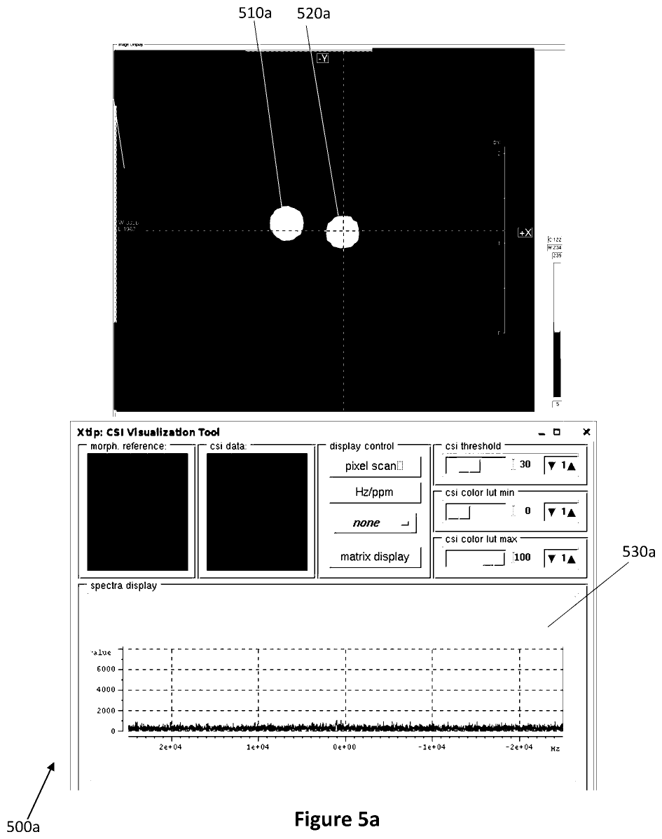

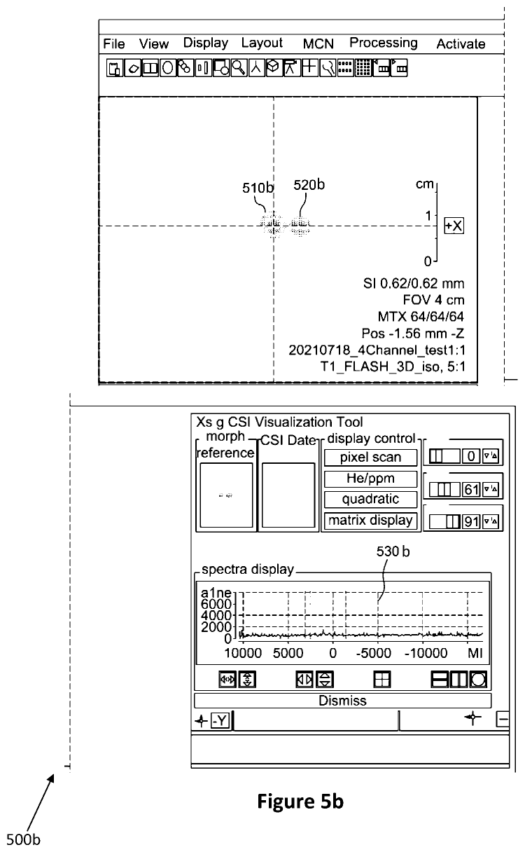

Referring FIG. 5a, there is an image 500a depicting MRI imaging 510a of a non-processed 13C-pyruvate mixture (right sample in upper diagram).

As is shown, the Chemical Shift spectrum 503a for non-processed 13C-pyruvate shows very weak signal comparing to the Hyperpolarized 13C-pyruvate mixture. No significant peak is present in the Chemical Shift spectrum 503a.

FIG. 5b is a line drawing illustration of FIG. 5a with 500b depicting MRI imaging 510b of a non-processed 13C-pyruvate mixture (right sample in upper diagram).

As is shown, the Chemical Shift spectrum 503b for non-processed 13C-pyruvate shows very weak signal comparing to the Hyperpolarized 13C-pyruvate mixture. No significant peak is present in the Chemical Shift spectrum 503b.

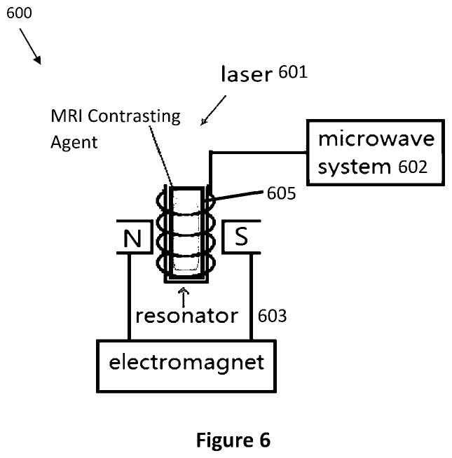

FIG. 6 shows a schematic representation of an embodiment of a hyperpolarisation system 600 as used in the present invention, which includes:
(i) A containment vessel 605 for holding the mixture of nanodiamonds and 13C metabolites in glassy state,
(ii) A laser for providing excitation 601,
(iii) A microwave system 602, and
(iv) A magnetic resonator 603.

### FURTHER EXPLANATIVE COMMENTS OF PRESENT INVENTION

In accordance with the present invention, a mixture of host vehicles for providing NV-centres for example nanodiamonds (as host vehicles) and 13C metabolite is prepared to form a solution.

Before use and for storage, the mixed solution of such host vehicles and 13C-metabolites is kept perfectly sealed under ambient condition. The mixture is transformed into glassy state only before it is used for hyperpolarisation in MRI imaging.

The solution mixture is then frozen to form a glassy state which may be considered one or more solid pieces of ice, which the constituents of the solution suspended therein, which obviates sedimentation.

In order to transform the mixture solution into a glassy state, the mixture is to be frozen in a freezer with temperature below −20° C. In an embodiment, the mixture is kept under temperature −35° C. and −80° C., while it has been shown that when the mixture is frozen at the temperature −80° C., it enables the fastest frozen rate of the mixture and a more durable frozen status.

A hyperpolarization process is then applied to the solid mixture. During hyperpolarization, the mixture will eventually melt and return back to a solution.

By the end of the hyperpolarization process, the mixture will be completely melted, and it is in a solution form.

In an embodiment, a further carrier is added to the mixture for forming a solution, such carrier includes one of or a mixture of water molecules, solvents, saline salt, and physical size of NV centre's host.

Thus, after filtering out the source of the NC centres, in this example nanodiamonds, the remaining solution can be injected into the body of an animal or a human, as a contrasting agent for enhanced MRI imaging, for investigative purposes of the body of the animal or human.

### ADVANTAGES OF PRESENT INVENTION

As will be understood, the present hyperpolarization process provides several advantages over those of the prior art, and advantageously, the use of a glassy structure provides the structure in a frozen state as such, which reduces or stops sedimentation of host vehicles and the 13C metabolite molecules at the bottom of the solution.

Advantageously, performing polarization whilst in the frozen state provides advantages, including a longer time to melt and ease of delivery to subjects for subsequent MRI imaging applications.

Existing methods include thermal shocking. It involves the use of electro paramagnetic agents as spin transfer medium. In this existing process, repeated thermal shocking travelling from room temperature to cryogenic temperature is required. Hence, the subsequent filtering procedure if the electro paramagnetic agents ia very difficult, and the machine of the existing technique is typically bulky and expensive due to the use of temperature control unit.

The present invention process, in contrast to the existing technology, utilises nanodiamonds as spin transfer medium. Nanodiamonds are biologically compactible and non-toxic to human bodies, which are also easy to be filtered out from the solution. More importantly, thermal cycle is not required in the process of the present invention. Hence, the operation procedure and the dimension of the machine thereof is much more simplified than the existing technology.

In accordance with the present invention, advantageously, the hyperpolarization of 13C-metabolite which can be achieved in ambient temperature and pressure, and subjects can benefit from freshly prepared and strong signal MRI metabolic probes.

1. A process for the polarization transfer between electron spin of Nitrogen Vacancy (NV) centre to nuclear spin of Carbon-13 labelled metabolites (13C-metabolites) in ambient conditions, said process including the steps of:
(i) providing a mixture including host vehicles which provide a source of NV centres, and 13C-metabolites;
(ii) transforming said mixture into a solid glassy state, wherein the spatial orientation of the host and electron spin state of NV centres are randomly distributed within said mixture in a solid state; and
(iii) applying a hyperpolarization process to the mixture in a solid state, wherein at the end of polarization transfer process, both electron spin of NV centres and nuclear spin of carbon-13 are strongly polarized in one direction at ambient temperature.

2. A process according to claim 1, wherein the NV centre in claim 1 is a source of electron spin to be polarized under hyperpolarization process in ambient conditions.

3. A process according to claim 1 or claim 2, wherein the pathway of spin transfer between electron spin of NV centre and 13C-metabolites is singular.

4. A process according to any one of claim 1 or 2, wherein the pathway of spin transfer between electron spin of NV centre and 13C-metabolites is plural as a result of spacing between molecules.

5. A process according to claim 4, wherein the spacing between molecules including spacing between hosts of NV centre, between 13C-metabolites, host of NV centre to 13C-metabolite, nuclear spin of 13C nuclear within host to 13C-metabolites; between charges including NV centres within same host, NV centres between different hosts; or between individual surrounding charges and corresponding spin state, magnetic impurities and the like.

6. A process according to claim 5, wherein the spacing between molecules is provided by a spacer wherein the spacer is water molecules, solvents, saline salt, or physical size of NV centre's host.

7. A process according to any one of the preceding claims, wherein the host of NV centre is a wide band gap material with high optical transparent for Deep UV to Green light.

8. A process according to claim 7, wherein the host of NV centre is a wide band gap material with high optical transparent for Deep UV to Green light in the range of from 200 nm to 600 nm.

9. A process according to any one of the preceding claims, wherein the host of NV centre is a micro-sized or nano-sized powder.

10. A process according to claim 9, wherein the host of NV centre is selected from the group including boron nitride, diamond or sapphire or the like.

11. A process according to any one of the preceding claims, wherein the host of NV centre has a size between 10 nm to 100 um.

12. A process according to any one of the preceding claims, wherein the 13C-metabolite is selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

13. A process according to any one of the proceeding claims, wherein the majority of final polarization of nuclear spin in 13C-metabolite is in same direction with few degrees discrepancy tolerance in any space coordinates.

14. A process according to any one of the proceeding claims, wherein the glassy state is provided by the quasi-lattice bonding between 13C-metabolites, hosts and other molecules of claim 12.

15. A process according to any one of the preceding claims, wherein the hyperpolarization process includes radiating microwave energy and coherent light to 13C-metabolites and hosts of NV centres mixture under application of magnetic field.

16. A process according to any one of the preceding claims, wherein the hyperpolarization process includes multi-cycle of excitation and manipulation of electron spin of NV centre and relaxation for spin transfer to nuclear spin of 13C-metabolites under ambient condition.

17. A process according to any one of the preceding claims, wherein the hyperpolarization of 13C-metabolite is provided at ambient conditions.

18. A process according to any one of the preceding claims, wherein the solid glassy state is formed by lowering the temperature of the mixture.

19. A process according to claim 18, wherein the temperature is lowered to below −20° C.

20. A process according to claim 18 or 19, wherein the temperature is lowered to −35° C. or −80° C.

21. A process for preparing a contrasting agent for MRI imaging of the body of a human or an animal for hyperpolarisation at ambient conditions, said process including the steps of:
(i) providing a mixture including host vehicles which provide a source of NV centres, and 13C-metabolites;
(ii) transforming said mixture into a solid glassy state, wherein the spatial orientation of the host and electron spin state of NV centres are randomly distributed within said mixture in a solid state.

22. A process according to claim 21, wherein the spacing between molecules including spacing between hosts of NV centre, between 13C-metabolites, host of NV centre to 13C-metabolite, nuclear spin of 13C nuclear within host to 13C-metabolites; between charges including NV centres within same host, NV centres between different hosts; or between individual surrounding charges and corresponding spin state, magnetic impurities and the like.

23. A process of claim 22, wherein the spacing between molecules is provided by a spacer wherein the spacer is water molecules, solvents, saline salt, or physical size of NV centre's host.

24. A process according to any one of claims 21 to 23, wherein the host of NV centre is a wide band gap material with high optical transparent for Deep UV to Green light.

25. A process according to claim 24, wherein the host of NV centre is a wide band gap material with high optical transparent for Deep UV to green lighting the range of from 200 nm to 600 nm.

26. A process according to any one of claims 21 to 25, wherein the solid glassy state is formed by lowering the temperature of the mixture.

27. A process according to claim 26, wherein the temperature is lowered to below −20° C.

28. A process according to claim 26 or claim 27, wherein the temperature is lowered to −35° C. or −80° C.

29. A process according to any one of claims 21 to 28, wherein the host of NV centre is a micro-sized or nano-sized powder.

30. A process according to claim29, wherein the host of NV centre is selected from the group including boron nitride, diamond or sapphire or the like.

31. A process according to any one of claims 21 to 30, wherein the host of NV centre has a size between 10 nm to 100 um.

32. A process according to any one of claims 21 to 31, wherein the 13C-metabolite is selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

33. A contrasting agent for MRI imaging of the body of a human or an animal for hyperpolarisation at ambient conditions, said contrasting agent comprising:
a mixture including host vehicles with NV centres and 13C-metabolites, wherein said mixture is provided in a solid glassy state, wherein the spatial orientation of the host and electron spin state of NV centres are randomly distributed within said mixture in a solid state.

34. A contrasting agent according to claim 33, wherein the spacing between molecules including spacing between hosts of NV centre, between 13C-metabolites, host of NV centre to 13C-metabolite, nuclear spin of 13C nuclear within host to 13C-metabolites; between charges including NV centres within same host, NV centres between different hosts; or between individual surrounding charges and corresponding spin state, magnetic impurities and the like.

35. A contrasting agent according to claim 33 or claim 34, wherein the spacing between molecules is provided by a spacer wherein the spacer is water molecules, solvents, saline salt, or physical size of NV centre's host.

36. A contrasting agent according to any one of claims 33 to 35, wherein the host of NV centre is a wide band gap material with high optical transparent for Deep UV to Green light.

37. A contrasting agent according to any one claims 33 to 36, wherein the host of NV centre is a wide band gap material with high optical transparent for Deep UV to Green lighting the range of from 200 nm to 600 nm.

38. A contrasting agent according to any one of claims 33 to 37, wherein the host of NV centre is a micro-sized or nano-sized powder.

39. A contrasting agent according to claim 38, wherein the host of NV centre is selected from the group including boron nitride, diamond or sapphire or the like.

40. A contrasting agent according to any one of claims 33 to 39, wherein the host of NV centre has a size between 10 nm to 100 um.

41. A contrasting agent according to any one of claims 33 to 40, wherein the 13C-metabolite is selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

42. A contrasting agent for MRI imaging of the body of a human or an animal for hyperpolarisation at ambient conditions, said contrasting agent comprising:
a mixture including host vehicles with NV centres and 13C-metabolites;
wherein said mixture is provided for subsequent transformation into a solid glassy state, such that the spatial orientation of the host and electron spin state of NV centres are randomly distributed within said mixture in a solid state.

43. A contrasting agent according to claim 42, wherein the host vehicles of NV centre is a micro-sized or nano-sized powder.

44. A contrasting agent according to claim 42 or claim 43, wherein the host of NV centre is selected from the group including boron nitride, diamond or sapphire or the like.

45. A contrasting agent according to any one of claims 42 to 44, wherein the host of NV centre has a size between 10 nm to 100 um.

46. A contrasting agent according to any one of claims 42 to 45, wherein the 13C-metabolite is selected from the group including Carbon-13 isotope enriched Acetic acid, Acetone, L-Alanine, Dimethyl Sulfoxide, Ethyl Pyruvate, D-Fructose, Fumaric acid, D-Glucose, L-Glutamic Acid, L0Glutamine, a-Ketoisocaprote (sodium salt), D-Mannitol, Propionic Acid, Pyruvic Acid, Sodium Acetate, Sodium Bicarbonate, Sodium Butyrate, Sodium L-lactate, Sodium Propionate, sodium Pyruvate, Succinic Acid, Urea or the like.

47. A hyperpolarisation system comprising;
(v) A containment vessel for receiving a contrasting agent according to any one of claims 27 to 35;
(vi) A laser for providing excitation;
(vii) A microwave system; and
(viii) A magnetic resonator.
